(19) United States
(12) Patent Application Publication
(10) Pub. No.: US 2022/0231660 A1
(43) Pub. Date: Jul. 21, 2022

(54) SURFACE ACOUSTIC WAVE (SAW) DEVICES WITH A DIAMOND BRIDGE ENCLOSED WAVE PROPAGATION CAVITY

(71) Applicant: QUALCOMM Incorporated, San Diego, CA (US)

(72) Inventors: Ranadeep Dutta, Del Mar, CA (US); Jonghae Kim, San Diego, CA (US); Je-Hsiung Lan, San Diego, CA (US)

(21) Appl. No.: 17/153,520

(22) Filed: Jan. 20, 2021

(51) Int. Cl. H03H 9/02; H03H 9/145; H03H 3/08

(52) U.S. Cl. CPC H03H 9/02582; H03H 3/08; H03H 9/145

(57) ABSTRACT

A surface acoustic wave (SAW) device includes a first interdigital transducer (IDT) and a second IDT each including interdigital electrodes disposed on a first surface of a substrate of piezoelectric material. The SAW device includes a diamond bridge enclosing an air cavity over a wave propagation region on the first surface of the substrate. The diamond bridge has a reduced height and provides improved thermal conductivity to avoid a reduction in performance and/or life span caused by heat generated in the SAW device. A process of fabricating a SAW device includes forming the first IDT and the second IDT in a metal layer on a first surface of a substrate comprising a piezoelectric material, the first IDT and the second IDT disposed in a wave propagation region of the first surface of the substrate, and forming a diamond bridge disposed above the wave propagation region.

### BACKGROUND

### I. Field of the Disclosure

The field of the disclosure relates to devices for filtering one or more ranges of frequencies in analog signals in radio-frequency (RF) electronic devices.

IL Background

Mobile wireless device manufacturers pack ever-increasing capabilities into hand-held sized packages. Increasing capability means that more electronic components must fit into the package. This trend drives a size reduction of electronic components used for radio-frequency (RF) signal processing. A challenge to miniaturizing electronic components is finding a way to provide the same function in a physically smaller electronic device. Another challenge to miniaturizing electronic components is created by a physically smaller device dissipating the same or similar amount of power, leading to the same or similar heat generation. Heat generated within a physically smaller device leads to higher operating temperatures in a smaller package, which increases the potential to affect device performance and its life span. Thus, there is a desire to find ways for more effectively dissipating heat when reducing the device size.

One device that has been employed in RF signal processing circuits provided in smaller electronic devices for signal filtering is a surface acoustic wave (SAW) filter. The SAW filter removes or reduces the energy in one or more bands of frequencies from an input analog signal. A SAW filter filters frequencies by transforming electromagnetic wave propagation into mechanical wave propagation on the surface of a substrate material. SAW filters can be implemented in die sized SAW packages (DSSPs) for use in a mobile device, as an example. SAW DSSP technology has been significant in the reduction of mobile device sizes. However, there is continued demand for further size reduction of RF electronic devices.

### SUMMARY OF THE DISCLOSURE

Aspects disclosed herein include surface acoustic wave (SAW) devices with a diamond bridge enclosed wave propagation cavity. Related fabrication methods are also disclosed. The SAW devices include a first interdigital transducer (IDT) and a second IDT each including interdigital electrodes disposed on a first surface of a substrate of piezoelectric material. The first IDT converts analog electrical radio-frequency (RF) signals into mechanical waves that propagate in a wave propagation region of the first surface of the substrate from the electrodes of the first IDT to the electrodes of the second IDT. The second IDT converts the mechanical waves back into analog electrical signals. The SAW device includes an enclosure that forms an air cavity above the first surface of the wave propagation region. The air cavity is provided to avoid interference with propagation of the mechanical waves in the substrate. The enclosure affects the overall height of the SAW device and also dissipates heat generated within the SAW device.

In exemplary aspects disclosed herein, the SAW device includes a diamond bridge enclosing an air cavity over the wave propagation region on the first surface of the substrate. The diamond bridge has a reduced height as compared to an enclosure formed by a cap substrate, for example, which enables miniaturization of RF circuits employing the SAW device as a filter for use in mobile devices. The thermal conductivity of the diamond bridge provides improved heat dissipation to avoid a reduction in performance and/or life span caused by heat generated in the SAW device.

In another exemplary aspect, processes of fabricating a SAW device including a diamond bridge are also disclosed. Disclosed processes include growing a diamond. layer over a buffer layer that is patterned to create a void to allow formation of a perimeter base of the diamond layer on the first surface of the substrate and around the wave propagation region. In a first process, the buffer layer is removed by deploying a buffer etch through the diamond material to create the air cavity. In a second process, a hole is formed in the diamond bridge to allow deployment of an etchant and removal of the etched buffer material through the hole.

In another exemplary aspect, a SAW device is disclosed. The SAW device includes a substrate comprising a piezoelectric material and a first surface. The SAW device includes a first IDT on the first surface of the substrate and a second IDT on the first surface of the substrate. The SAW device also includes a diamond bridge disposed over a wave propagation region between the first IDT and the second IDT in the first surface of the substrate and enclosing an air cavity above the wave propagation region.

In another exemplary aspect, a method of fabricating a SAW device is disclosed. The method includes forming a first IDT and a second IDT in a metal layer on a first surface of a substrate comprising a piezoelectric material, the first IDT and the second IDT disposed in a wave propagation region of the first surface of the substrate. The method also includes forming a diamond bridge disposed over the wave propagation region.

In another exemplary aspect, a circuit package including a package substrate and a SAW device coupled to the package substrate is disclosed. The SAW device in the circuit package includes a substrate comprising a piezoelectric material and a first surface. The SAW device includes a first IDT on the first surface of the substrate and a second IDT on the first surface of the substrate. The SAW device also includes a diamond bridge disposed over a wave propagation region between the first IDT and the second IDT in the first surface of the substrate and enclosing an air cavity above the wave propagation region.

### BRIEF DESCRIPTION OF THE FIGS.

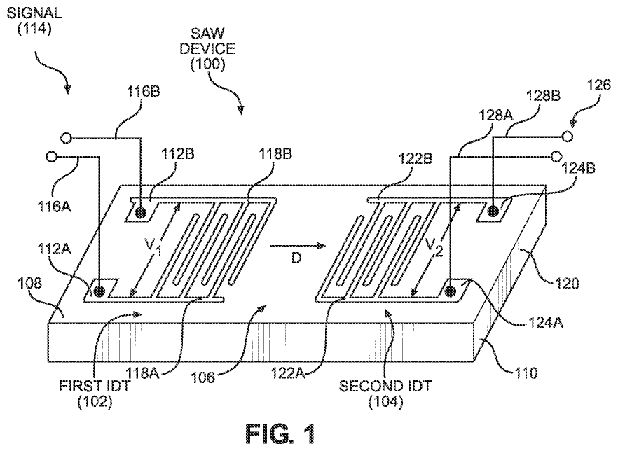

FIG. 1 is a perspective view of interdigital transducers (IDTs) in a wave propagation region on a surface of a substrate in a surface acoustic wave (SAW) device without an enclosure forming an air cavity;

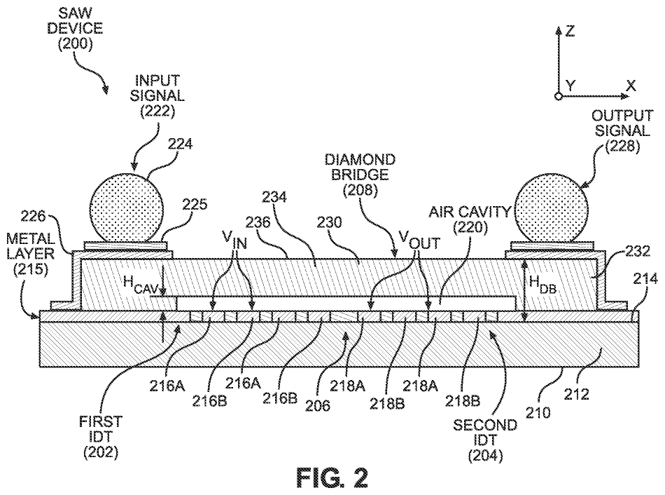

FIG. 2 is a cross-sectional side view of an exemplary SAW device including a diamond bridge enclosing a wave propagation region of a first surface of a substrate and. an air cavity above the wave propagation region for a reduced total device height, improved heat dissipation capability, and reduced mechanical deformation due to heating;

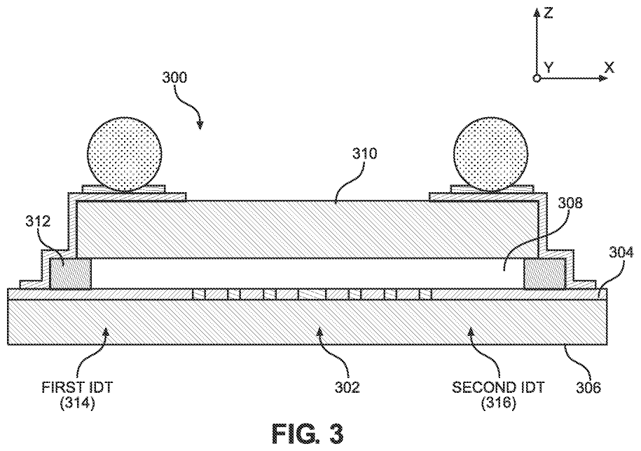

FIG. 3 is a cross-sectional side view of a conventional SAW device in which an air cavity is formed over a wave propagation region of a first surface of a functional substrate by a cap layer of a cap substrate bonded to a polymer frame;

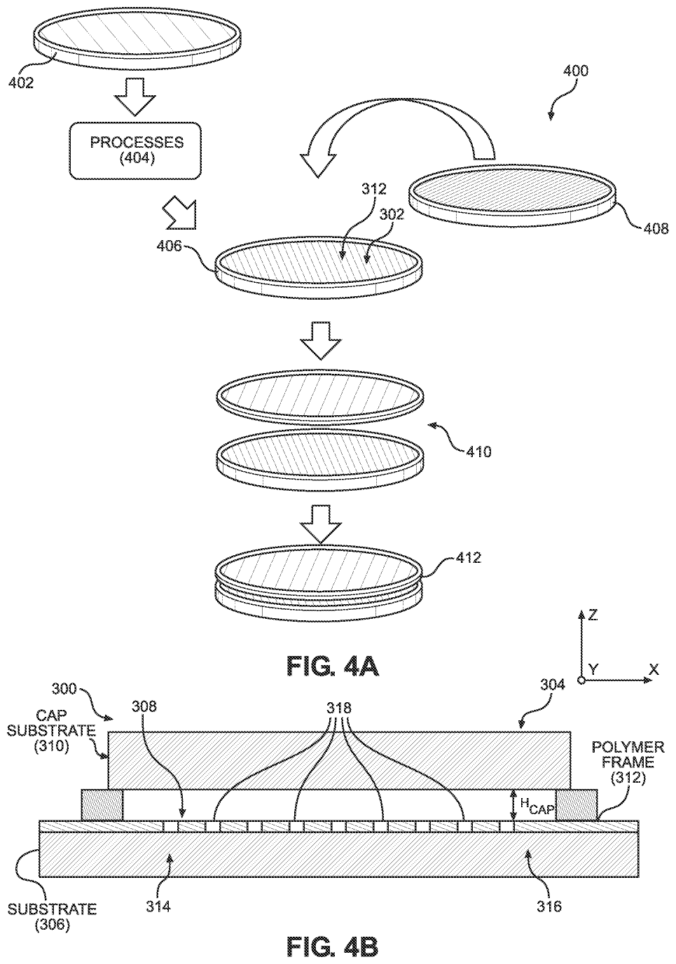

FIG. 4A is a diagram illustrating a process for fabricating the conventional SAW device in FIG. 3;

FIG. 4B is a cross-sectional side view of the conventional SAW device in a stage of fabrication according to the process in FIG. 4A;

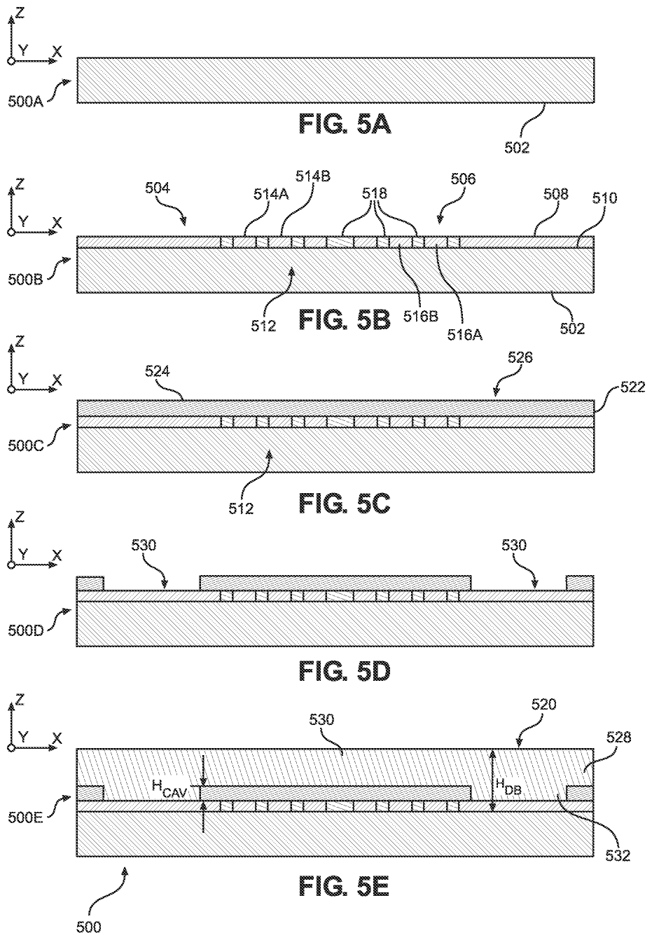

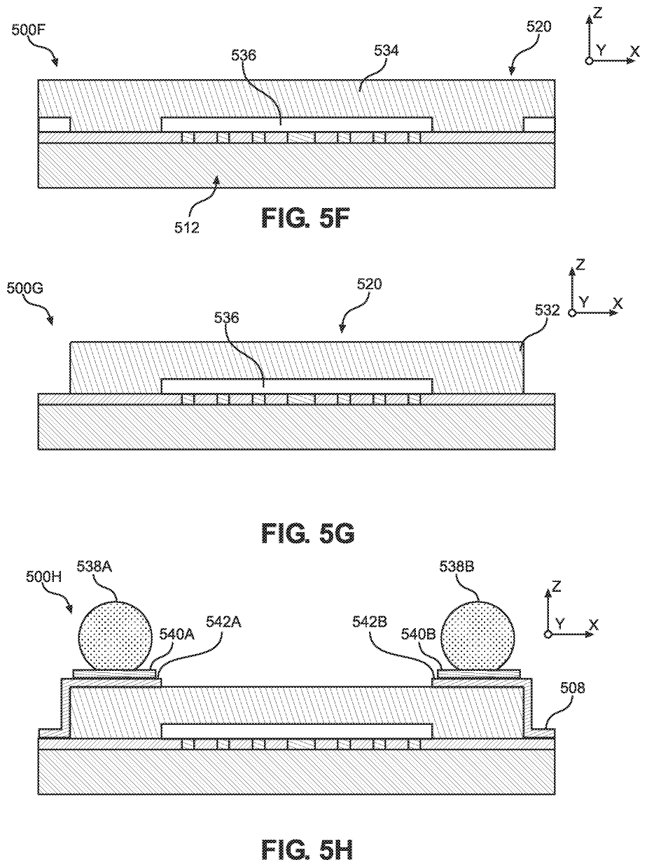

FIGS. 5A-5H illustrate exemplary fabrication stages in an exemplary process for fabricating the SAW device in FIG. 2;

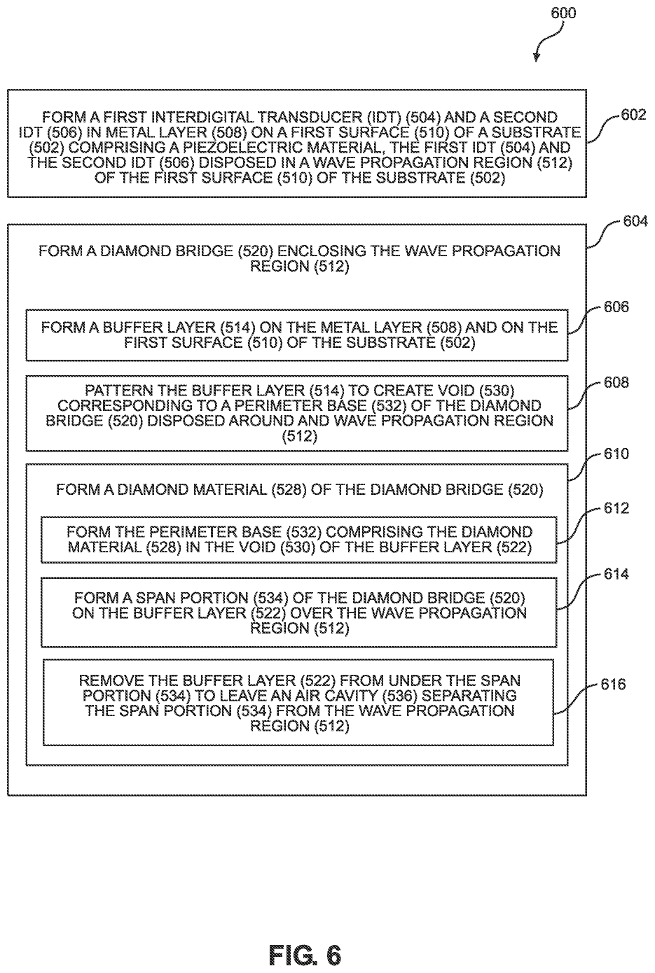

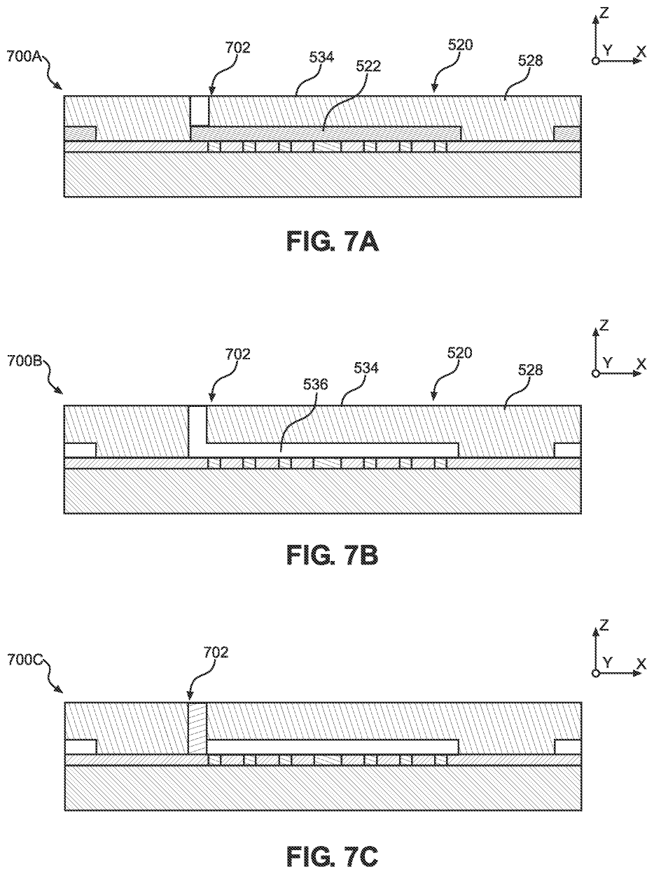

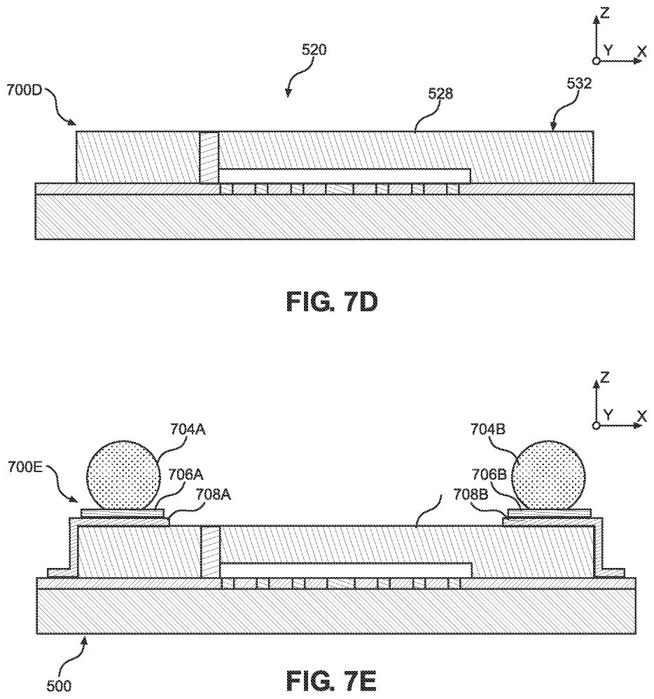

FIG. 6 is a flowchart illustrating an exemplary process for fabricating the SAW device in FIG. 2 corresponding to the exemplary fabrication stages illustrated in FIGS. 5A-5E and continuing in either FIGS. 5F-5H or FIGS. 7A-7E;

FIGS. 7A-7E illustrate a set of exemplary fabrication stages, in a second process option proceeding from the stages in FIG. 5A-5E, for fabricating of a second example of the SAW device in FIG. 2;

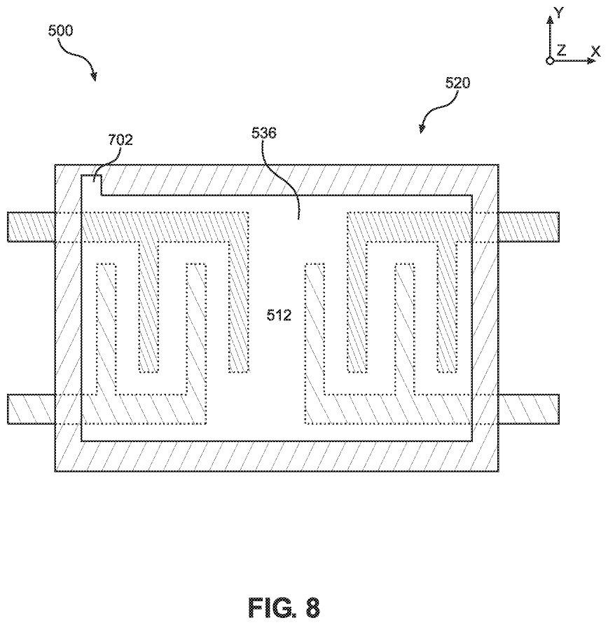

FIG. 8 is a top plan view of the SAW device shown in FIG. 7A-7B illustrating an exemplary location of a release hole in the diamond bridge;

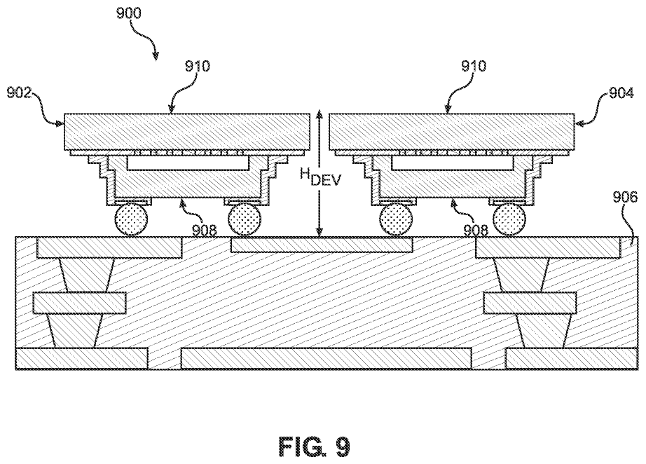

FIG. 9 is a cross-sectional side view of an exemplary circuit package in which a plurality of the SAW devices in FIG. 2 are mounted on a substrate;

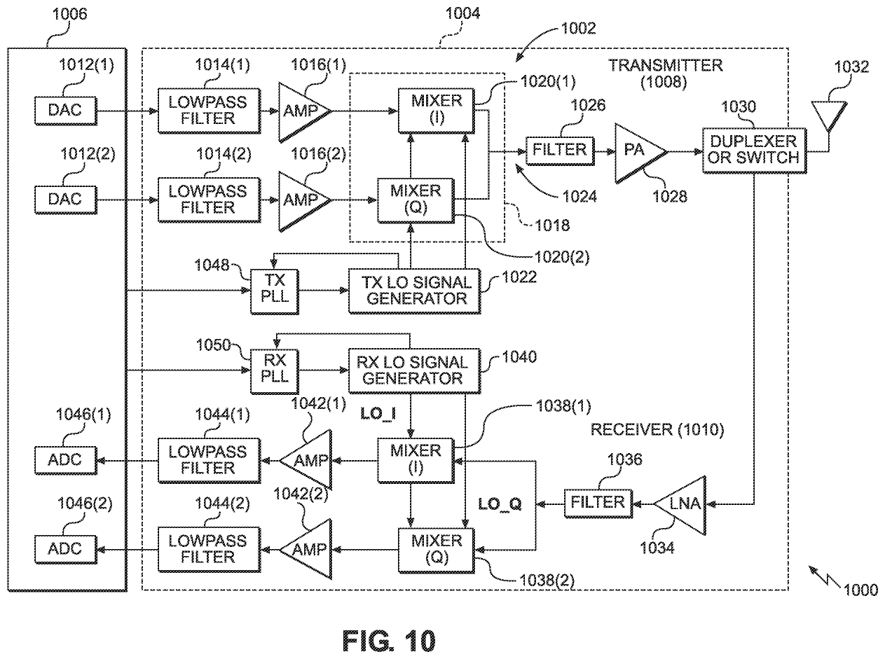

FIG. 10 is a block diagram of an exemplary wireless communications device that includes a radio-frequency (RF) module including the SAW device in FIG. 2; and

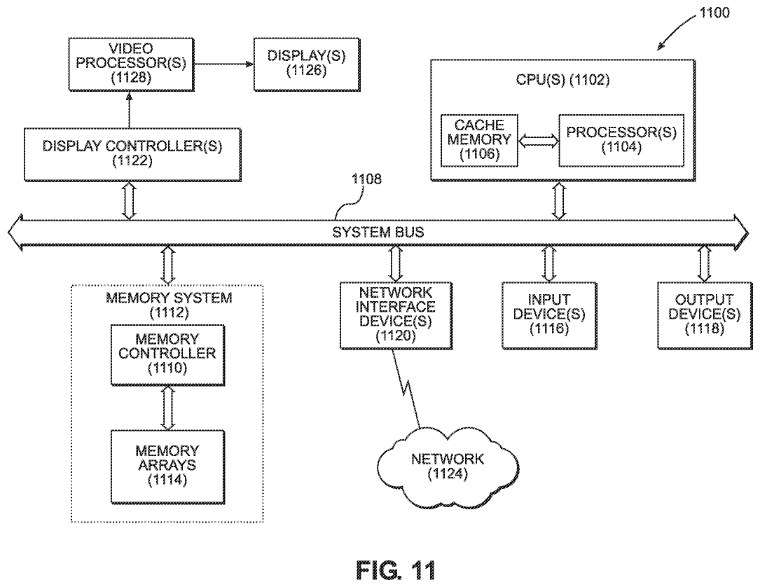

FIG. 11 is a block diagram of an exemplary processor-based system that includes a SAW device including a diamond bridge enclosing an air cavity over a wave propagation region of a substrate for a reduced total device height and an improved heat dissipation capability, as illustrated in FIG. 2, and according to any of the aspects disclosed herein.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include surface acoustic wave (SAW) devices with a diamond bridge enclosed wave propagation cavity. Related fabrication methods are also disclosed. The SAW devices include a first interdigital transducer (IDT) and a second IDT each including interdigital electrodes disposed on a first surface of a substrate of piezoelectric material. The first IDT converts analog electrical radio-frequency (RF) signals into mechanical waves that propagate in a wave propagation region of the first surface of the substrate from the electrodes of the first IDT to the electrodes of the second IDT. The second IDT converts the mechanical waves back into analog electrical signals. The SAW device includes an enclosure that forms an air cavity above the first surface of the wave propagation region. The air cavity is provided to avoid interference with propagation of the mechanical waves in the substrate. The enclosure affects the overall height of the SAW device and also dissipates heat generated within the SAW device.

In exemplary aspects disclosed herein, the SAW device includes a diamond bridge enclosing an air cavity over the wave propagation region on the first surface of the substrate. The diamond bridge has a reduced height as compared to an enclosure formed by a cap substrate, for example, which enables miniaturization of RF circuits employing the SAW device as a filter for use in mobile devices. The thermal conductivity of the diamond bridge provides improved heat dissipation to avoid a reduction in performance and/or life span caused by heat generated in the SAW device.

In another exemplary aspect, processes of fabricating a SAW device including a diamond bridge are also disclosed. The processes include growing a diamond layer over a buffer layer that is patterned to create a void to allow formation of a perimeter base of the diamond layer on the first surface of the substrate and around the wave propagation region. In a first process, the buffer layer is removed by deploying a buffer etch through the diamond material to create the air cavity. In a second process, a hole is formed in the diamond bridge to allow deployment of an etchant and removal of the etched buffer material through the hole.

FIG. 1 is a perspective view of a conventional SAW device 100 provided for comparison and to explain the exemplary aspects discussed below. The SAW device 100 includes first and second IDTs 102 and 104 in a wave propagation region 106 on a first surface 108 of a substrate 110. The first IDT 102 includes contacts 112A and 112B for receiving a signal 114 provided on wires 116A and 116B. The contact 112A is coupled to electrodes 118A and the contact 112B is coupled to electrodes 118B. The electrodes 118A are interdigitated or interleaved with the electrodes 118B. The signal 114 creates a voltage Vi between the electrodes 118A and 118B in the first surface 108. The substrate 110 is formed of a piezoelectric material 120, which expands and contracts in the presence of the voltage V1 based on the signal 114. The expansion and contraction of the piezoelectric material 120 generates mechanical waves (not shown). Mechanical waves that propagate in a direction through the wave propagation region 106 to the second IDT 104 create a voltage V2 between electrodes 122A and 122B, which are coupled, respectively, to contacts 124A and 124B. An output signal 126 is supplied on wires 128A and 128B based on the signal 114. Propagation of the mechanical waves in the first surface 108 of the substrate 110 would be impeded by a protective layer disposed on the first surface 108, but is not impeded by air immediately above the first surface 108, as shown in FIG. 1. When the SAW device 100 is employed in a package, such as a die sized SAW package (DSSP) (not shown), an enclosure is provided on the first surface 108 to maintain an air cavity above the wave propagation region 106.

FIG. 2 is a cross-sectional side view of an exemplary SAW device 200 including a first IDT 202, a second IDT 204, and a wave propagation region 206 between the first IDT 202 and the second IDT 204 with a diamond bridge 208 disposed over the wave propagation region 206. The SAW device 200 has similar electrical function to the SAW device 100 in FIG. 1. The illustration in FIG. 2 is provided for reference in the discussion of exemplary aspects presented below. The SAW device 200 includes a substrate 210 including a piezoelectric material 212. The piezoelectric material 212 is a material with a high electromechanical coupling coefficient, such as lithium tantalate (LiTaO₃) or lithium niobate (LiNbO₃). Other options for the piezoelectric material 212 include aluminum nitride and scandium carbide. The substrate 210 includes a first surface 214 that extends in an X-axis direction and a Y-axis direction that is orthogonal to the X-axis direction. The SAW device 200 includes the first IDT 202 on the first surface 214 of the substrate 210. The first IDT 202 includes a first plurality of electrodes 216A interleaved with a second plurality of electrodes 216B. The SAW device 200 includes the second IDT 204 on the first surface 214, and the second IDT 204 includes a third plurality of electrodes 218A interleaved with a fourth plurality of electrodes 218B. The first IDT 202 and the second IDT 204 are formed in a patterned metal layer 215 disposed. on the first surface 214 of the substrate 210.

The diamond bridge 208 is disposed over the wave propagation region 206 in the first surface 214 of the substrate 210. The wave propagation region 206 is between the first IDT 202 and the second IDT 204. The diamond bridge 208 also encloses an air cavity 220 above the wave propagation region 206, A height H_{CAV} of the air cavity 220 extends in a Z-axis direction orthogonal to the X-axis and Y-axis directions. The diamond bridge 208 provides a reduced total device height of the SAW device 200, improved heat dissipation capability, and reduced mechanical deformation compared to a conventional SAW device, as explained below.

In one example, the SAW device 200 may be a SAW filter that receives an input signal 222, which is an RF signal. The SAW device 200 may be integrated into an RF front end module and configured to block frequencies of the input signal 222. The input signal 222 applies a time-varying voltage V_{IN} between a solder bump 224 and another solder bump (not shown). The solder bump 224 is coupled to the first plurality of electrodes 216A by a contact 225 and a conductive element 226, and the other (not shown) solder bump is similarly coupled to the second plurality of electrodes 216B. The first plurality of electrodes 216A and the second plurality of electrodes 216B transmit the input signal 222 to the piezoelectric material 212 of the substrate 210. The piezoelectric material 212 expands or contracts in the presence of the voltage V_{IN}. When the voltage V_{IN} changes periodically, the voltage V_{IN} causes time-varying expansion and contraction of the piezoelectric material 212, which generates mechanical waves (not shown). Mechanical waves that propagate through the wave propagation region 206 to the second IDT 204 create a voltage V_{OUT} between the third plurality of electrodes 218A and the fourth plurality of electrodes 218B. In this example, the SAW device 200 generates an output signal 228 based on the input signal 222.

Transmission of the input signal 222 through the first plurality of electrodes 216A and the second plurality of electrodes 216B and transmission of the output signal 228 through the third plurality of electrodes 218A and the fourth plurality of electrodes 218B causes thermal heating of the substrate 210, especially near the first and second IDTs 202 and 204. Heating of the substrate 210 increases electrical resistance, which wastes power, Heating of the substrate 210 also causes the piezoelectric material 212 to expand in the wave propagation region 206. Expansion of the substrate 210 due to heating can change a distance between the first plurality of electrodes 216A and the second. plurality of electrodes 216B and between the third plurality of electrodes 218A and the fourth plurality of electrodes 218B. Such change in distance affects the dimensions of the waves and causes transmission phase loss, altering performance of the SAW device 200. Excessive heating can also cause premature device failure.

To manage the generated heat, an exemplary aspect of the SAW device 200 is the diamond bridge 208 that encloses the wave propagation region 206 and the air cavity 220 above the first surface 214 of the substrate 210. The diamond bridge 208 is formed of a diamond material 230. Allotropes of carbon, such as graphite and diamond, are usually credited with having the highest thermal conductivities of any materials at room temperature. Thus, the diamond bridge 208 is an excellent thermal conductor for moving heat out of the substrate 210. The diamond bridge 208 may be thermally coupled to a thermal interface material (TIM), a heat sink, or an air interface, for example, to effectively move excess heat away from the SAW device 200.

The diamond bridge 208 includes a perimeter base 232 extending around the wave propagation region 206 of the first surface 214. The diamond bridge 208 also includes a span portion 234 extending in the X-axis and Y-axis directions above the wave propagation region 206 of the first surface 214 from a first side of the perimeter base 232 to a second side of the perimeter base 232. The perimeter base 232 is disposed on the patterned metal layer 215 and on the first surface 214 of the substrate 210. The perimeter base 232 is between 45 and 55 micrometers (μm) in width.

The diamond bridge 208 has a total height H_{DB} in the range of 25-35 μm from the first surface 214 of the substrate 210 to a surface 236 of the diamond bridge 208. A thickness of the substrate 210 is in the range of 50-70 μm. Thus, the height H_{DB} of the diamond bridge 208 is between 35% and 65% of a thickness of the substrate 210 in the Z-axis direction. The height H_{CAV} of the air cavity 220 is between 4 and 6 μm, to allow the mechanical waves to propagate in the first surface 214 unimpeded. Thus, the height H_{CAV} of the air cavity 220 is between 12% and 25% of the height H_{DB} of the diamond bridge 208 from the first surface 214 of the substrate 210 to the surface 236 of the diamond bridge 208 (i.e., of the span portion 234). Outside dimensions of the perimeter base 232 of the diamond bridge 208 extend about 1 millimeter (mm) along a first side (e.g., in the Y-axis direction) and about 1 mm along a second side orthogonal to the first side (e.g., in the X-axis direction).

The diamond material 230 provides the additional benefits of high rigidity and a low co-efficient of thermal expansion (CTE). Thus, in response to heating of the substrate 210, as the heat from within the substrate 210 is conducted through the diamond bridge 208, the diamond bridge 208 expands at a much lower rate than the substrate 210. The rigidity of the diamond bridge 208, which is affixed to the substrate 210, inhibits mechanical deformation (i.e., due to heating) of the substrate 210, thereby reducing the negative performance effects caused by heating in the SAW device 200.

FIG. 3 is a cross-sectional side view of a conventional SAW device 300 provided for purposes of comparison to the SAW device 200 employing the diamond bridge 208 enclosing the wave propagation region 206 in FIG. 2. The SAW device 300 includes a wave propagation region 302 in a first surface 304 of a substrate 306. An air cavity 308 over the wave propagation region 302 is enclosed by a cap substrate 310 bonded to a polymer frame 312, which is fabricated in a process summarized in FIGS. 4A and 4B below. The polymer frame 312 is disposed on first and second IDTs 314 and 316 and the substrate 306 of the SAW device 300. In contrast to the perimeter base 232 of the diamond bridge 208 in the SAW device 200, the polymer frame 312 is a poor thermal conductor that does not effectively transfer heat away from the substrate 306. In addition, as described below, the cap substrate 310 is formed of a piezoelectric material similar to the substrate 306 or may be a silicon (Si) wafer. Thus, the cap substrate 310 does not effectively move heat from the polymer frame 312 and out of the SAW device 300 like the diamond bridge 208 in FIG. 2. Furthermore, a CTE of the cap substrate 310 is not significantly lower than that of the substrate 306 and may be the same, so the cap substrate 310 does not inhibit mechanical deformation of the substrate 310 in the presence of internal heating.

FIG. 4A is a diagram illustrating a process 400 for fabricating the conventional SAW device 300 in FIG. 3 for comparison to distinguish the exemplary processes disclosed herein. An acoustic substrate 402 of the piezoelectric material for the substrate 306 is subjected to processes 404 to partially form a plurality of SAW devices 300, the processes 404 producing a processed wafer 406. The processes 404 include forming the IDTs 314 and 316 including electrodes 318 (shown in FIG. 4B). The processes 404 also include forming the polymer frames 312 around the wave propagation regions 302 of each of the SAW devices 300 as shown in FIG. 3. Next, a cap wafer 408 is disposed on top of the processed wafer 406. The cap wafer 408 is bonded to the polymer frames 312 in each of the SAW devices 300 of the processed wafer 406 in a bonding step 410 to create a wafer assembly 412. The wafer assembly 412 is diced to reduce portions of the cap wafer 408 in each of the SAW devices 300 to an area of the cap substrate 310 shown in FIG. 4B. The wafer assembly 412 is also diced or cut through the processed wafer 406 to cingulate the SAW devices 300.

FIG. 4B is a cross-sectional side view of the conventional SAW device 300 in a stage of fabrication according to the process in FIG. 4A. The SAW device 300 shown in FIG. 4B shows the electrodes 318 of the IDTs 314 and 316 on the substrate 306, the polymer frame 312 formed on the IDTs 314 and 316, and the cap substrate 310 bonded onto the polymer frame 312 to create the air cavity 308. As noted above, the polymer frame 312 and the cap substrate 310 are formed of materials with much lower thermal conductivity than the diamond bridge 208 in FIG. 2. A height of the polymer frame 312 is about 50 μm, and the height of the cap substrate 310 above the first surface 304 of the substrate 306 is in the range of 50-70 μm. Thus, a total height H_{CAP} of the enclosure in the conventional SAW device 300 is in the range of 100-120 μm.

In contrast to the process shown in FIG. 4A, FIGS. 5A-5H are diagrams illustrating cross-sectional side views of a SAW device 500 in fabrication stages during an exemplary process 600 illustrated in a flowchart in FIG. 6. The process 600 is employed for fabricating a SAW device 500 that includes the diamond bridge 208 enclosing the wave propagation region 206 as shown in FIG. 2. The SAW device 500 may be the SAW device 200 including the diamond bridge 208 in FIG. 2, providing increased thermal conductivity, reduced mechanical deformation in response to heating, and reduced height for a smaller package size. In a first exemplary stage 500A in FIG. 5A, a substrate 502 is formed of a piezoelectric material with a high electromechanical coupling coefficient, such as LiTaO₃ or LiNbO₃, for example.

FIG. 5B illustrates an exemplary fabrication stage 500B of step 602 of the process 600 in FIG. 6 including forming a first IDT 504 and a second IDT 506 in a metal layer 508 on a first surface 510 of the substrate 502 comprising the piezoelectric material, the first IDT 504 and the second IDT 506 disposed in a wave propagation region 512 of the first surface 510 of the substrate 502.

Forming the first MT 504 and the second IDT 506, in one example, includes forming the metal layer 508 on the first surface 510 of the substrate 502. The metal layer 508 may be formed of aluminum (Al) or copper (Cu). The metal layer 508 may also be implemented by a layer of non-metal conductive material such as doped polysilicon or silicide. Forming the first 504 includes patterning the metal layer 508 using photolithography and etching processes, for example, to remove portions of the metal layer 508. The metal layer 508 is patterned to form first electrodes 514A interleaved with second electrodes 514B to form the first IDT 504. The metal layer 508 is also patterned to form third electrodes 516A interleaved with fourth electrodes 516B of the second IDT 506. The first and second IDTs 504 and 506 are formed in a wave propagation region 512 of the first surface 510 of the substrate 502. Depending on the type of SAW device 500 (e.g., filter, oscillator, transformer, etc.) the metal layer 508 may include other structures in addition to the first IDT 504 and the second IDT 506 in the wave propagation region 512. An insulation material 518 is disposed between the first and second electrodes 514A, 514B and the third and fourth electrodes 516A, 516B.

FIG. 5C illustrates an exemplary fabrication stage 500C of step 604 of the process 600 in FIG. 6 including forming a diamond bridge 520 (shown in stage 500E) over the wave propagation region 512. In this regard, the illustration of fabrication stage 500C of FIG. 5C also show the step 606 in process 600 in FIG. 6 of forming the diamond bridge 520 including forming a buffer layer 522 on the metal layer 508 and on the first surface 510 of the substrate 502. In the example in FIG. 5C, the buffer layer 522 is formed by first depositing an oxide layer 524, such as a layer of silicon dioxide (SiO₂). Thus, the terms buffer layer 522 and oxide layer 524 may be used interchangeably regarding this example. In one example, forming the buffer layer 522 includes treating the buffer layer 522 to damage a surface 526 of the buffer layer 522. For example, treating the buffer layer 522 may include inducing ultrasonic damage to the surface 526 of the oxide layer 524 by methanol agitation. Other known methods for inducing damage to a layer of SiO₂ are also within the scope of the present disclosure. The damage to the surface 526 of the oxide layer 524 (buffer layer 522) reduces a rate of growth of a diamond. material 528 (see stage 500E) on the buffer layer 522 compared to a rate of growth of the diamond material 528 on an undamaged surface.

As shown in the illustration of fabrication stage 500D of FIG. 5D of the step 608 of the process 600 in FIG. 6, forming the diamond bridge 520 further includes patterning the buffer layer 522 to create a void 530 corresponding to a perimeter base 532 of the diamond bridge 520 disposed around the wave propagation region 512. The illustration of stage 500E shows that the buffer layer 522 has a thickness H_{CAV} which is the height of the air cavity 308 in FIG. 3. The void 530 in the buffer layer 522 exposes the metal layer 508 and the first surface 510 of the substrate 502. The void 530 extends around the perimeter of the wave propagation region 512 and is created where the perimeter base 532 of the diamond bridge 520 will be formed, as shown in FIG. 5E.

FIG. 5E illustrates fabrication stage 500E in the step 610 of process 600 in FIG. 6 including forming the diamond material 528 of the diamond bridge 520. Forming the diamond material 528 includes forming the perimeter base 532 of the diamond material 528 in the voids 530 of the butler layer 522 (step 612 of process 600 in FIG. 6) and forming a span portion 534 of the diamond bridge 520 on the buffer layer 522 over the wave propagation region 512 (step 614 of process 600 in FIG. 6). Forming the perimeter base 532 and the span portion 534 of the diamond bridge 520 includes growing the diamond material 528, which may be achieved by chemical vapor deposition (CVD). In particular, the diamond material 528 may be formed in a plasma-enhanced CVD process using a direct-current (DC) discharge to generate the plasma. Alternatively, a hot-filament CVD (HFCVD) process may be used to form the diamond material 528 in the void 530 and on the buffer layer 522. Due to the damage induced on the surface 526 of the oxide layer 524, a rate of formation of the diamond material 528 is slower than a rate of formation of the diamond material 528 in the void 530 (i.e., on the first surface 510 of the substrate 502 and on the metal layer 508). Due to this difference in growth rate, the diamond bridge 520 may be grown to a desired height H_{DB} on the buffer layer 522 in approximately the same time that the perimeter base 532 is grown to the height H_{DB} in the void 530, The diamond material 528 is thinned and/or planarized in a chemical mechanical polishing (CMP) process, using an ion beam or a laser.

The process 600 in FIG. 6 further includes, as illustrated in fabrication stage 500F shown in FIG. 5F, the step 616 of removing the buffer layer 522 from under the span portion 534 to leave an air cavity 536 separating the span portion 534 from the wave propagation region 512. In this regard, a first option for removing the buffer layer 522 is illustrated among further fabrication stages in FIG. 5F. FIGS. 7A and 7B below illustrate further fabrication stages including an alternative option for removing the buffer layer 522.

The fabrication stage 500F illustrated in FIG. 5F shows the step of removing the buffer layer 522 under the span portion 534 of the diamond bridge 520 further comprises etching out the buffer layer 522 under the diamond bridge 520 by employing a buffer oxide etch process. According to such process, an etchant penetrates the diamond material 528, chemically decomposes the buffer layer 522 and removes the buffer layer 522 residue through the diamond material 528. As a result, the buffer layer 522 is removed from under the span portion 534 of the diamond bridge 520 to leave the air cavity 536 separating the span portion 534 from the wave propagation region 512 of the first surface 510 of the substrate 502. An enclosed air cavity 536 protects the wave propagation region 512 from any materials that would interfere with propagation of mechanical waves in or on the first surface 510.

In the fabrication stage 500G in FIG. 5G, the diamond material 528 outside the perimeter base 532 is removed to singulate the diamond bridge 520 enclosing the air cavity 536. Fabrication stage 500H in FIG. 5H illustrates solder bumps 538A and 538B on respective contacts 540A and 540B. The solder bumps 538A and 538B are coupled to the metal layer 508 in the first and second IDTs 504 and 506 by conductive elements 542A and 542B. The solder bumps 538A and 538B are employed to mount the SAW device 500 to a package (not shown), for example. The conductive elements 542A and 542B are formed in a process including depositing a titanium (Ti) adhesion layer and Cu seed layer, followed by patterned copper nickel (CuNi) traces. The contacts 540A and. 54013 are formed as a patterned gold (Au) under bump metal (UBM). The solder bumps 538A, 538B are tin-silver-copper (Sn—Ag—Cu) solder balls. Other connective materials and structures could also be employed for coupling the SAW device 500 to a package.

Alternative fabrication stages 700A-700E shown in FIGS. 7A-7E illustrate alternative steps for removing the buffer layer according to step 616 in the process 600 in FIG. 6. The fabrication stage 700A in FIG. 7A is an alternative next fabrication stage after the fabrication stage 500E in FIG. 5E. FIG. 7A shows that a release hole 702 is formed in the span portion 534 of the diamond bridge 520. In one example, the release hole 702 may be formed by a masked etch of the diamond material 528, where the etch is an inductively coupled plasma (ICP) reactive ion etch (RIE) using a ratio of argon (Ar) and oxygen (O₂) in the plasma. The process for forming the release hole 702 is selective, stopping at the buffer layer 522.

As shown in the fabrication stage 700B in FIG. 7B, removing the buffer layer 522 under the span portion 534 of the diamond bridge 520 in the alternative process further comprises deploying a buffer hydrofluoric acid (HF) etch through the release hole 702 and removing the buffer layer 522. The buffer etch process described with reference to FIG. 5A is able to penetrate the diamond material 528, but employing the release hole 702 enables more complete removal of the decomposed buffer layer 522. (oxide layer 524), reducing an amount of residual SiO₂ or etch byproducts in the air cavity 536 that could interfere with wave propagation in the first surface 510 of the substrate 502.

In fabrication stage 700C in FIG. 7C, the illustration shows that the release hole 702 is filled using a physical vapor deposition (PVD) fill of tungsten (W), Cu, or SiO₂ followed by planarization using CMP. Fabrication stage 700D in FIG. 7D corresponds to fabrication stage 500G, in which the diamond material 528 outside the perimeter base 532 is removed to singulate the diamond bridge 520. Fabrication stage 700E in FIG. 7E corresponds to fabrication stage 500H, in which diamond solder bumps 704A, 704B, contacts 706A, 706B, and conductive elements 708A, 708B are disposed on the SAW device 500.

FIG. 8 is a top plan view of the SAW device 500 fabricated according to the fabrication stages 500A-500E in FIGS. 5A-5E and in the fabrication stage 700A in FIG. 7A, illustrating a location of the release hole 702 for deploying an etchant under the diamond bridge 520 and for removal of the buffer layer 522 (see FIG. 5C). As shown in this view, the release hole 702 may be formed outside the air cavity 536 to avoid interference with the air cavity 536 and the wave propagation region 512.

FIG. 9 is an illustration of a circuit package 900 in which SAW devices 902 and 904, corresponding to the SAW device 200 in FIG. 2, are coupled to a package substrate 906. In one example, the circuit package 900 may further comprise an RF signal processing circuit (not shown). In such example, the SAW devices 902 and 904 may be SAW filters configured to block frequencies of an RF signal. Diamond bridges 908 of the SAW devices 902 and 904 reduce a height H_{DEV} of the SAW devices 902 and 904 extending above a package substrate 906 and also provide improved thermal conduction of heat generated in piezoelectric substrates 910.

FIG. 10 illustrates an exemplary wireless communications device 1000 that includes RF components formed from one or more integrated circuits (ICs) 1002, wherein any of the ICs 1002 can include a SAW device including a diamond bridge enclosing a wave propagation region of a first surface of a substrate and an air cavity above the wave propagation region for a reduced total device height, improved heat dissipation capability, and reduced mechanical deformation due to heating, as illustrated in any of FIGS. 2, 5H, and 7E, and according to any of the aspects disclosed herein. The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and. frequency bands. All or a portion of the transceiver 1004 may be implemented on one or more analog ICs, radio-frequency ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals from a TX LO signal generator 1022 through mixers 1020(1), 1020(2) to provide an upconverted signal 1024. A filter 1026 filters the upconverted signal 1024 to remove undesired signals caused by the frequency upconversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Downconversion mixers 1038(1), 1038(2) mix the output of the filter 1036 with I and Q RX LO signals (i.e., LU_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency upconversion, while the RX LO signal generator 1040 generates the I and Q RX LO signals used for frequency downconversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Wireless communications devices 1000 that each include a SAW device including a diamond bridge enclosing a wave propagation region of a first surface of a substrate and an air cavity above the wave propagation region for a reduced total device height, improved heat dissipation capability, and reduced mechanical deformation due to heating, as illustrated in any of FIGS. 2, 5H, and 7E, and according to any of the aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

In this regard, FIG. 11 illustrates an example of a processor-based system 1100 including a SAW device including a diamond bridge enclosing a wave propagation region of a first surface of a substrate and an air cavity above the wave propagation region for a reduced total device height, improved heat dissipation capability, and reduced mechanical deformation due to heating, as illustrated in any of FIGS. 2, 5H, and 7E, and according to any aspects disclosed herein. In this example, the processor-based system 1100 includes one or more central processor units (CPUs) 1102, which may also be referred to as CPU or processor cores, each including one or more processors 1104. The CPU(s) 1102 may have cache memory 1106 coupled to the processor(s) 1104 for rapid access to temporarily stored data. As an example, the processor(s) 1104 could include a SAW device including a diamond bridge enclosing a wave propagation region of a first surface of a substrate and an air cavity above the wave propagation region for a reduced total device height, improved heat dissipation capability, and reduced mechanical deformation due to heating, as illustrated in any of FIGS. 2, 5H, and 7E, and according to any aspects disclosed herein. The CPU(s) 1102 is coupled to a system bus 1108 and can intercouple master and slave devices included in the processor-based system 1100. As is well known, the CPU(s) 1102 communicates with these other devices by exchanging address, control, and data information over the system bus 1108. For example, the CPU(s) 1102 can communicate bus transaction requests to a memory controller 1110 as an example of a slave device. Although not illustrated in FIG. 11, multiple system buses 1108 could be provided, wherein each system bus 1108 constitutes a different fabric.

Other master and slave devices can be connected to the system bus 1108. As illustrated in FIG. 11, these devices can include a memory system 1112 that includes the memory controller 1110 and one or more memory arrays 1114, one or more input devices 1116, one or more output devices 1118, one or more network interface devices 1120 and one or more display controllers 1122, as examples. Each of the memory system 1112, the one or more input devices 1116, the one or more output devices 1118, the one or more network interface devices 1120, and the one or more display controllers 1122 can include a SAW device including a diamond bridge enclosing a wave propagation region of a first surface of a substrate and an air cavity above the wave propagation region for a reduced total device height, improved heat dissipation capability, and reduced mechanical deformation due to heating, as illustrated in any of FIGS. 2, 5H, and 7E, and according to any of the aspects disclosed herein. The input device(s) 1116 can include any type of input device, including, but not limited to, input keys, switches, voice processors, etc. The output device(s) 1118 can include any type of output device, including, but not limited to, audio, video, other visual indicators, etc. The network interface device(s) 1120 can be any device configured to allow exchange of data to and from a network 1124. The network 1124 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1120 can be configured to support any type of communications protocol desired.

The CPU(s) 1102 may also be configured to access the display controller(s) 1122 over the system bus 1108 to control information sent to one or more displays 1126. The display controller(s) 1122 sends information to the display(s) 1126 to be displayed via one or more video processors 1128, which process the information to be displayed into a format suitable for the display(s) 1126. The display(s) 1126 can include any type of display, including, but not limited to, a cathode ray tube (CRT), a liquid crystal display (LCD), a plasma display, a light emitting diode (LED) display, etc. The display controller(s) 1122, displays) 1126, and/or the video processor(s) 1128 can include a SAW device including a diamond bridge enclosing a wave propagation region of a first surface of a substrate and an air cavity above the wave propagation region for a reduced total device height, improved heat dissipation capability, and reduced mechanical deformation due to heating, as illustrated in any of FIGS. 2, 5H, and 7E, and according to any of the aspects disclosed herein.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:
1. A surface acoustic wave (SAW) device, comprising:
   a substrate comprising a piezoelectric material and a first surface;
   a first interdigital transducer (IDT) on the first surface of the substrate;
   a second IDT on the first surface of the substrate; and
   a diamond bridge disposed over a wave propagation region between the first IDT and the second IDT of the first surface of the substrate and enclosing an air cavity above the wave propagation region.
2. The SAW device of clause 1, wherein:
   the first surface of the substrate extends in a first direction and a second direction orthogonal to the first direction; and
   the diamond bridge comprises:
      a perimeter base extending around e wave propagation region of the first surface; and
      a span portion extending in the first and second directions above the wave propagation region of the first surface from a first side of the perimeter base to a second side of the perimeter base,
3. The SAW device of clause 2, wherein:
   the first IDT and the second IDT are formed in a patterned metal layer disposed on the first surface of the substrate;
   the first IDT comprises a first plurality of electrodes interleaved with a second plurality of electrodes;
   the second IDT comprises a third plurality of electrodes interleaved with a fourth plurality of electrodes; and
   the perimeter base of the diamond bridge is disposed on the patterned metal layer and on the first surface of the substrate.
4. The SAW device of any one of clauses 2 to 3, wherein the perimeter base has a width of 45-55 micrometers (μm).
5. The SAW device of any one of clauses 2 to 4, wherein:
   a height of the air cavity extends in a third direction orthogonal to the first surface between the first surface of the substrate and the span portion of the diamond bridge; and
   the height of the air cavity is between 12% and 25% of the height of the diamond bridge from the first surface of the substrate to a surface of the span portion.
6. The SAW device of any one of clauses 1 to 5, wherein a height of the diamond bridge is between 35% and 65% of a thickness of the substrate.
7. The SAW device of any one of clauses 2 to 5, wherein the perimeter base extends 1 millimeter (mm) in the first direction and 1 mm in the second direction.
8. The SAW device of any one of clauses 1 to 7, integrated into a radio-frequency (RF) front end module.
9. The SAW device of any one of clauses 1 to 8 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
10. A method of fabricating a surface acoustic wave (SAW) device, the method comprising:
   forming a first interdigital transducer (IDT) and a second IDT in a metal layer on a first surface of a substrate comprising a piezoelectric material, the first IDT and the second IDT disposed in a wave propagation region of the first surface of the substrate; and
   forming a diamond bridge disposed over the wave propagation region.
11. The method of clause 10, wherein forming the diamond bridge disposed over the wave propagation region comprises:
   forming a buffer layer on the metal layer and on the first surface of the substrate;
   patterning the buffer layer to create voids corresponding to a perimeter base of the diamond bridge disposed around the wave propagation region;
   forming a diamond material of the diamond bridge comprising:
      forming the perimeter base comprising the diamond material in the voids of the buffer layer; and
      forming a span portion of the diamond bridge on the buffer layer over the wave propagation region; and
   removing the buffer layer from under the span portion to leave an air cavity separating the span portion from the wave propagation region.
12. The method of clause 11, wherein forming the buffer layer further comprises treating the buffer layer to reduce a rate of formation of the diamond material.
13. The method of any one of clauses 10 to 12, wherein forming the first IDT and the second IDT comprises:
   forming the metal layer on the first surface of the substrate; and
   patterning the metal layer to form:
      the first IDT comprising a first plurality of electrodes interleaved with a second plurality of electrodes; and
      the second IDT comprising a third plurality of electrodes interleaved with a fourth plurality of electrodes.
14. The method of clause 12, wherein:
   forming the buffer layer comprises depositing an oxide layer; and
   treating the buffer layer further comprises damaging a surface of the oxide layer.
15. The method of clause 14, wherein:
   depositing the oxide layer comprises forming a silicon dioxide (SiO₂) layer; and
   damaging the surface of the oxide layer comprises inducing ultrasonic damage to the oxide layer by methanol agitation.
16. The method of any one of clauses 10 to 15, wherein forming the diamond bridge further comprises thinning and/or planarizing a surface of the diamond bridge.
17. The method of any one of clauses 11, 12, 14, and 15, wherein removing the buffer layer under the span portion of the diamond bridge further comprises etching out the buffer layer under the diamond bridge by a buffer oxide etch process.
18. The method of any one of clauses 11, 12, 14, 15, and 17, wherein:
   removing the buffer layer under the span portion of the diamond bridge further comprises:
   forming a release hole in the span portion of the diamond bridge;
   etching out the buffer layer through the release hole to form the air cavity; and
   plugging the release hole to seal the air cavity.
19. The method of clause 18, wherein:
   forming the release hole in the span portion of the diamond bridge comprises etching the diamond bridge by inductively coupled plasma reactive ion etching with an argon (Ar) and oxygen (O₂) plasma.
20. A circuit package, comprising:
   a package substrate; and
   a surface acoustic wave (SAW) device coupled to the package substrate, the SAW device comprising:
      a substrate comprising a piezoelectric material and a first surface;
      a first interdigital transducer (IDT) on the first surface of the substrate;
      a second IDT on the first surface of the substrate; and
      a diamond bridge disposed over a wave propagation region between the first IDT and the second IDT of the first surface of the substrate and enclosing an air cavity above the wave propagation region.

What is claimed is:

1. A surface acoustic wave (SAW) device, comprising:
a substrate comprising a piezoelectric material and a first surface;
a first interdigital transducer (IDT) on the first surface of the substrate;
a second IDT on the first surface of the substrate; and
a diamond bridge disposed over a wave propagation region between the first IDT and the second IDT of the first surface of the substrate and enclosing an air cavity above the wave propagation region.

2. The SAW device of claim 1, wherein:
the first surface of the substrate extends in a first direction and a second direction orthogonal to the first direction; and
the diamond bridge comprises:
a perimeter base extending around the wave propagation region of the first surface; and
a span portion extending in the first and second directions above the wave propagation region of the first surface from a first side of the perimeter base to a second side of the perimeter base.

3. The SAW device of claim 2, wherein:
the first IDT and the second IDT are formed in a patterned metal layer disposed on the first surface of the substrate;
the first IDT comprises a first plurality of electrodes interleaved with a second plurality of electrodes;
the second IDT comprises a third plurality of electrodes interleaved with a fourth plurality of electrodes; and
the perimeter base of the diamond bridge is disposed on the patterned metal layer and on the first surface of the substrate.

4. The SAW device of claim 2, wherein the perimeter base has a width of 45-55 micrometers (μm).

5. The SAW device of claim 2, wherein:
a height of the air cavity extends in a third direction orthogonal to the first surface between the first surface of the substrate and the span portion of the diamond bridge; and
the height of the air cavity is between 12% and 25% of the height of the diamond bridge from the first surface of the substrate to a surface of the span portion.

6. The SAW device of claim 1, wherein a height of the diamond bridge is between 35% and 65% of a thickness of the substrate.

7. The SAW device of claim 2, wherein the perimeter base extends 1 millimeter (mm) in the first direction and 1 mm in the second direction.

8. The SAW device of claim 1, integrated into a radio-frequency (RF) front end module.

9. The SAW device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

10. A method of fabricating a surface acoustic wave (SAW) device, the method comprising:
forming a first interdigital transducer (IDT) and a second IDT in a metal layer on a first surface of a substrate comprising a piezoelectric material, the first IDT and the second IDT disposed in a wave propagation region of the first surface of the substrate; and
forming a diamond bridge disposed over the wave propagation region.

11. The method of claim 10, wherein forming the diamond bridge disposed over the wave propagation region comprises:
forming a buffer layer on the metal layer and on the first surface of the substrate;
patterning the buffer layer to create voids corresponding to a perimeter base of the diamond bridge disposed around the wave propagation region;
forming a diamond material of the diamond bridge comprising:
forming the perimeter base comprising the diamond material in the voids of the buffer layer; and
forming a span portion of the diamond bridge on the buffer layer over the wave propagation region; and
removing the buffer layer from under the span portion to leave an air cavity separating the span portion from the wave propagation region.

12. The method of claim 11, wherein forming the buffer layer further comprises treating the buffer layer to reduce a rate of formation of the diamond material.

13. The method of claim 10 wherein forming the first IDT and the second IDT comprises:
forming the metal layer on the first surface of the substrate; and
patterning the metal layer to form:
the first IDT comprising a first plurality of electrodes interleaved with a second plurality of electrodes; and
the second IDT comprising a third plurality of electrodes interleaved with a fourth plurality of electrodes.

14. The method of claim 12, wherein:
forming the buffer layer comprises depositing an oxide layer; and
treating the buffer layer further comprises damaging a surface of the oxide layer.

15. The method of claim 14, wherein:
depositing the oxide layer comprises forming a silicon dioxide (SiO₂) layer; and
damaging the surface of the oxide layer comprises inducing ultrasonic damage to the oxide layer by methanol agitation.

16. The method of claim 10, wherein forming the diamond bridge further comprises thinning and/or planarizing a surface of the diamond bridge.

17. The method of claim 11, wherein removing the buffer layer under the span portion of the diamond bridge further comprises etching out the buffer layer under the diamond bridge by a buffer oxide etch process.

18. The method of claim 11, wherein:
removing the buffer layer under the span portion of the diamond bridge further comprises:
forming a release hole in the span portion of the diamond bridge;
etching out the buffer layer through the release hole to form the air cavity; and
plugging the release hole to seal the air cavity.

19. The method of claim 18, wherein:
forming the release hole in the span portion of the diamond bridge comprises etching the diamond bridge by inductively coupled plasma reactive ion etching with an argon (Ar) and oxygen (O₂) plasma.

20. A circuit package, comprising:
a package substrate; and
a surface acoustic wave (SAW) device coupled to the package substrate, the SAW device comprising:
a substrate comprising a piezoelectric material and a first surface;
a first interdigital transducer (IDT) on the first surface of the substrate;
a second IDT on the first surface of the substrate; and
a diamond bridge disposed over a wave propagation region between the first IDT and the second IDT of the first surface of the substrate and enclosing an air cavity above the wave propagation region.
